(19) United States
(12) Patent Application Publication
(10) Pub. No.: US 2026/0262417 A1
(43) Pub. Date: Sep. 3, 2026

(54) DISPLAY, DISPLAY DEVICE AND METHOD FOR MANUFACTURING DISPLAY

(71) Applicants: Beijing BOE Technology Development Co., Ltd., Beijing (CN); BOE TECHNOLOGY GROUP CO., LTD., Beijing (CN)

(72) Inventors: Haoran WANG, Beijing (CN); Song ZHANG, Beijing (CN); Chunyan XIE, Beijing (CN); Shiming SHI, Beijing (CN)

(73) Assignees: Beijing BOE Technology Development Co., Ltd., Beijing (CN); BOE TECHNOLOGY GROUP CO., LTD., Beijing (CN)

(21) Appl. No.: 18/995,873

(22) PCT Filed: Aug. 28, 2024
(86) PCT No.: PCT/CN2024/115188

§ 371 Date: Jan. 17, 2025

(30) Foreign Application Priority Data
Sep. 28, 2023 (CN) 202311277599.9

(51) Int. Cl. H10K 59/80

(52) U.S. Cl. CPC H10K 59/873

(57) ABSTRACT

The present disclosure provides a display panel, an adhesive layer and a cover plate which are arranged in a stacked manner, wherein a light emitting side of the display panel has a display area and a peripheral area surrounding the display area; wherein the adhesive layer comprises an edge adhesive layer arranged in the peripheral area and a main adhesive layer covering the display area, and a shear storage modulus of the edge adhesive layer is greater than a shear storage modulus of the main adhesive layer. The display area is bonded by the main adhesive layer, and the peripheral area is bonded by the edge adhesive layer with a larger shear storage modulus, so as to improve the bonding ability between the peripheral area of the light emitting side of the display panel and the cover plate, improve the reliability of the display.

### CROSS REFERENCE

This disclosure claims the benefit of Chinese application No. 202311277599.9 filed on Sep. 28, 2023 and entitled “DISPLAY, DISPLAY DEVICE AND METHOD FOR MANUFACTURING DISPLAY”, which is incorporated herein by reference in their entirety.

### TECHNICAL FIELD

The present disclosure relates to a technical field of display panel, and in particular, to a display, a display device, and a method for manufacturing the display.

### BACKGROUND

OLED spherical display refers to a flexible OLED assembled on a hard substrate or a transparent cover plate with a complete or partial spherical shape through curved surface bonding. The bonding of the spherical display module, due to the characteristics of non-developable curved surfaces such as spheres, makes the edges tend to debond and wrinkle after assembly. The debonding and wrinkling trends develop faster in high temperature and high humidity environments.

It should be noted that the information disclosed in the above background technology section is only used to enhance the understanding of the background of the present disclosure, and therefore may include information that does not constitute the prior art known to ordinary technicians in the field.

### SUMMARY

the present disclosure is to overcome the deficiencies of the above-mentioned prior art and provide a display, a display device and a method for manufacturing the display to improve the phenomenon of debonding, wrinkling and the like at an edge of the display in a high temperature and high humidity environment.

According to one aspect of the present disclosure, a display is provided, comprising a display panel, an adhesive layer and a cover plate which are arranged in a stacked manner, wherein a light emitting side of the display panel has a display area and a peripheral area surrounding the display area;
wherein the adhesive layer comprises an edge adhesive layer arranged in the peripheral area and a main adhesive layer covering the display area, and a shear storage modulus of the edge adhesive layer is greater than a shear storage modulus of the main adhesive layer.

In an exemplary embodiment of the present disclosure, at least a portion of a surface of the cover plate is a curved surface.

In an exemplary embodiment of the present disclosure, at least a portion of the surface of the cover plate is a non-developable curved surface.

In an exemplary embodiment of the present disclosure, the shear storage modulus of the edge adhesive layer at 25° C. is not less than 300 kPa.

In an exemplary embodiment of the present disclosure, the main adhesive layer and the edge adhesive layer do not overlap each other.

In an exemplary embodiment of the present disclosure, the display panel has a first thickness at an edge of the peripheral area, and the display panel has a second thickness at an inner side of the peripheral area, wherein the first thickness is at least 10 micrometers smaller than the second thickness; and
wherein the edge adhesive layer covers at least a portion of the edge of the peripheral area.

In an exemplary embodiment of the present disclosure, the display panel is provided with a thinned area at an edge of the peripheral area, and the edge adhesive layer covers at least a portion of the thinned area.

In an exemplary embodiment of the present disclosure, a width of the edge adhesive layer is not less than 0.15 mm.

In an exemplary embodiment of the present disclosure, the edge adhesive layer is black.

In an exemplary embodiment of the present disclosure, the edge adhesive layer is transparent or translucent.

In an exemplary embodiment of the present disclosure, the edge adhesive layer is at least one of modified acrylic resin, modified polyurethane resin, modified organosiloxane resin, and modified epoxy resin.

In an exemplary embodiment of the present disclosure, the display further includes a back support layer disposed on a non-light emitting side of the display panel;
wherein the edge adhesive layer extends out of an edge of the display panel and is connected to the back support layer.

In an exemplary embodiment of the present disclosure, the display panel is a flexible display panel.

In an exemplary embodiment of the present disclosure, a surface of an edge region of the cover plate is a curved surface.

In an exemplary embodiment of the present disclosure, the edge adhesive layer is made of the same material as the main adhesive layer and the shear storage modulus of the edge adhesive layer at 25° C. is not less than 300 kPa.

In an exemplary embodiment of the present disclosure, a display device is provided, comprising the above-mentioned display.

In an exemplary embodiment of the present disclosure, a method for manufacturing a display is provided, comprising following steps:
providing a display panel, wherein a light emitting side of the display panel has a display area and a peripheral area surrounding the display area;
forming an adhesive layer on the light emitting side of the display panel, wherein the adhesive layer comprises an edge adhesive layer arranged in the peripheral area and a main adhesive layer covering the display area, and wherein a shear storage modulus of the edge adhesive layer is greater than a shear storage modulus of the main adhesive layer;
providing a cover plate on a side of the adhesive layer away from the display panel.

The present disclosure provides a display, a display device and a method for manufacturing the display, wherein a display panel is assembled into a cover plate by bonding, and the display area is bonded by the main adhesive layer, and the peripheral area is bonded by the edge adhesive layer with a larger shear storage modulus, so as to improve the bonding ability between the peripheral area of the light emitting side of the display panel and the cover plate, improve the reliability of the display, especially the stability of the edge of the display in a high temperature and high humidity environment for a long time, and at the same time, improve the impact resistance and drop resistance of the edge of the display without affecting optical characteristics of the display area on the light emitting side of the display panel.

It is to be understood that the foregoing general description and the following detailed description are exemplary and explanatory only and are not restrictive of the present disclosure.

### BRIEF DESCRIPTION OF THE DRAWINGS

The accompanying drawings herein are incorporated into the specification and constitute a part of the specification, illustrate embodiments consistent with the present disclosure, and together with the specification are used to explain the principles of the present disclosure. Obviously, the accompanying drawings described below are only some embodiments of the present disclosure, and for those skilled in the art, other accompanying drawings may be obtained based on these accompanying drawings without creative work.

FIG. 1 is a schematic diagram of a circular display structure according to an embodiment of the present disclosure.

FIG. 2 is a schematic diagram of a square display structure according to an embodiment of the present disclosure.

FIG. 3 is a front view of a cover plate in the circular display according to some embodiments of the present disclosure.

FIG. 4 is a schematic diagram of a cross-sectional structure of the cover plate in a first embodiment, with a cutting position being A=A.

FIG. 5 is a schematic diagram of the cross-sectional structure of the cover plate in a second embodiment, with the cutting position being A=A.

FIG. 6 is a schematic diagram of the cross-sectional structure of the cover plate in a third embodiment, with the cutting position being A=A.

FIG. 7 is a schematic diagram of the cross-sectional structure of the cover plate in a fourth embodiment, with the cutting position is A=A.

FIG. 8 is a schematic diagram of the cross-sectional structure of the cover plate in a fifth embodiment, with the cutting position being A=A.

FIG. 9 is a schematic diagram of a display stacking structure according to an embodiment of the present disclosure.

FIG. 10 is a schematic diagram of the display stacking structure according to an embodiment of the present disclosure.

FIG. 11 is a schematic diagram of the display stacking structure according to an embodiment of the present disclosure.

FIG. 12 is schematic diagrams of the display stacking structure according to an embodiment of the present disclosure.

FIG. 13 is a schematic diagram showing the relative positional relationship between an edge adhesive layer and a main adhesive layer, a display area on a light emitting side of a display panel, and an ink area of the cover plate in FIG. 11.

FIG. 14 is a schematic diagram showing the relative positional relationship between the edge adhesive layer and the main adhesive layer, the display area on the light emitting side of the display panel, and the ink area of the cover plate in FIG. 10.

FIG. 15 is a schematic diagram showing the relative positional relationship between the edge adhesive layer and the main adhesive layer, the display area on the light emitting side of the display panel, and the ink area of the cover plate, wherein the edge adhesive layer extends out of the display panel and is connected to a back support frame.

FIG. 16 is a schematic diagram of edge structures of the edge adhesive layer, the cover plate and the display panel in an embodiment of the present disclosure.

FIG. 17 is schematic diagram of the edge structures of the edge adhesive layer, the cover plate and the display panel in an embodiment of the present disclosure.

FIG. 18 is schematic diagram of the edge structures of the edge adhesive layer, the cover plate and the display panel in an embodiment of the present disclosure.

FIG. 19 is a schematic diagram of a display edge stacking segment gap structure according to an embodiment of the present disclosure.

FIG. 20-1 to FIG. 20-9 are schematic diagrams of structures of display manufacture processes according to an embodiment of the present disclosure.

FIG. 21-1 to FIG. 21-10 are schematic diagrams of the structures of display manufacturing processes according to an embodiment of the present disclosure.

FIG. 22 is a flow chart of a method for manufacturing the display of the present disclosure.

The main components in the drawings are described as follows:
Display panel: PNL;
Display area: AA;
Outer area: BB;
Substrate: SBT;
Driver layer: DRL;
Pixel layer: PIXL;
Thin film encapsulation layer: TFE;
Touch function layer: TSL;
Color film layer: CFL;

Reference numerals of other components are as follows:
1. Display; 2. Cover plate; 4. Main adhesive layer; 5. Edge adhesive layer; 6. Polarizing layer; 7. Back support layer; 71. Back film; 72. Foam; 73. Copper foil; 8. Carrier film; 9. Display driver chip.

### DETAILED DESCRIPTION

Example embodiments will now be described more fully with reference to the accompanying drawings. However, the example embodiments can be implemented in a variety of forms and should not be construed as limited to the embodiments set forth herein; rather, these embodiments are provided so that the present disclosure will be comprehensive and complete and fully convey the concepts of the example embodiments to those skilled in the art. The same reference numerals in the figures represent the same or similar structures, and thus their detailed description will be omitted. In addition, the drawings are only schematic illustrations of the present disclosure and are not necessarily drawn to scale.

Although relative terms such as “on” are used in this specification to describe the relative relationship of one component of the illustration to another component, these terms are used in this specification only for convenience, such as according to the orientation of the examples described in the drawings. It is understood that if the device of the illustration is turned upside down, the component described as “on” will become the component “under”. When a structure is “on” other structures, it may mean that the structure is formed integrally on the other structure, or that the structure is “directly” disposed on the other structure, or that the structure is “indirectly” disposed on the other structure through another structure.

The terms “the”, “said,” and “at least one” are used to indicate the presence of one or more elements/components/etc. ; the terms “including” and “having” are used to indicate an open-ended inclusive meaning and mean that additional elements/components/etc. may be present in addition to the listed elements/components/etc.

In the present disclosure, when describing that a structure A and a structure B are not overlapped, it means that the structure A and the structure B are arranged in the same film layer, and there is no overlapping part between an orthographic projection of the structure A on a substrate SBT and an orthographic projection of the structure B on the substrate SBT.

In the present disclosure, when describing a structure C and a structure D are overlapped, it means that the structure C and the structure D are arranged in the same film layer, and there is no overlapping part between the orthographic projection of structure C on the substrate SBT and the orthographic projection of structure D on the substrate SBT.

In the present disclosure, a structure layer E is located on the side of a structure layer F away from the substrate SBT, which may be understood as the structure layer E is formed on the side of the structure layer F away from the substrate SBT. When the structure layer F is a patterned structure, part of the structure layer E may also be located at the same physical height of the structure layer E or lower than the physical height of the structure layer E, wherein the substrate SBT is a height reference.

The definitions of a developable curved surface and a non-developable curved surface involved in this article are as follows:

Developable curved surface: a developable curved surface is a curved surface with zero Gaussian curvature at every point on it, and is a special curved surface in differential geometry that may be transformed into a plane while preserving its length (i.e., a developable curved surface is a curved surface that may be unfolded into a plane, such as a cylinder or a cone).

Non-developable curved surface: a non-developable curved surface is a curved surface that cannot be unfolded into a plane, such as an ellipse, an elliptical paraboloid, and a curved surface of revolution. Generally, only ruled curved surfaces are divided into developable curved surfaces and non-developable curved surfaces, and all hyperbolic curved surfaces are non-developable curved surfaces.

The lamination of a display panel PNL and a cover plate 2 refers to laminating a layer of the cover plate 2 on the display panel PNL. Because surface hardness of the display panel PNL is low, laminating a layer of the cover plate 2 on its surface may not only protect the display panel PNL, but also beautify the product. The lamination method of the cover plate 2 and the display panel PNL is the same as the lamination method of the touch screen and the display panel PNL, which is basically divided into two categories: frame lamination and full lamination:

Frame lamination is simply to use a double-sided tape to stick the cover plate 2 and the display panel PNL together, with a gap and air between the cover plate 2 and the display panel PNL. Full lamination is to use OCA optical glue or water glue to stick the cover plate 2 and the display panel PNL together, without any gap or air, just as the cover plate 2 and the display panel PNL are originally a whole.

The products laminated by the above two methods have their own characteristics:

Frame lamination: The lamination cost is low and it is not easy to be damaged. Even if it is not laminated well, just tear off the double-sided tape and laminate it again. The maintenance cost is low. Even if one of the cover plate 2 and the display panel PNL is damaged, the other one may continue to be used. But at the same time, because there is air between the cover plate 2 and the display panel PNL, it is easy for dust, water and impurities to enter, and the diffuse reflection is also serious. The visual effect is not as good as the full lamination.

Full lamination: The full lamination process eliminates gaps and air between the cover plate 2 and the display panel PNL, effectively preventing dust, water vapor condensation and other impurities from entering between the cover plate 2 and the display panel PNL, and maintaining the cleanliness of the display 1; at the same time, it greatly reduces light reflection, making the display effect of the display 1 better; products using the full lamination process may more effectively reduce the interference of noise on the touch signal and improve the smoothness of touch operation. Due to the characteristics of OCA optical glue or water glue, products using the full lamination process have a thinner body, a narrower frame, and a more beautiful visual effect.

The disadvantages of full lamination are also obvious. Its process is more complicated, the production yield is lower, the equipment investment cost is higher, the maintenance cost is high, the workshop production environment requirements are higher, and rework is more difficult. If one of the cover plate 2 and the display panel PNL is broken, it is not easy to remove the other intact one.

In general, full lamination provides a better experience, but the cost is higher. Although frame lamination is not as good as full lamination, the cost is lower.

The cover plate 2 involved in the present disclosure includes a substrate and an ink layer. The substrate has a window area and a frame area, and the frame area is located outside the window area. The ink layer in the present disclosure is formed in an outer area of the back of the frame area (that is, the middle of the ink layer is hollowed out to form a display area AA of the display panel PNL). During the processing and manufacturing of the display panel PNL, an adhesive layer covers a middle area of the back of the substrate (corresponding to the display area AA) and the back of the ink layer, thereby realizing a connection between the cover plate 2 and other layers of the display panel PNL.

It is relatively easy to understand that the window area in the present disclosure is formed to be surrounded by the ink layer. Specifically, the substrate is made of a transparent material, usually made of any one of glass, polyethylene glycol terephthalate (PET), polystyrene-Acrylonitrile (PSA), polycarbonate (PC), and polymethyl methacrylate (PMMA). The material of the ink layer is formed by solidifying light-proof ink. In the cover plate 2 structure, the ink layer located on the back of the frame area may block light from penetrating the substrate. Since there is no ink material in the window area, light may pass smoothly. In a specific implementation process, an inner edge of the ink layer is flat, so that the display 1 equipped with the cover plate 2 has a better display function.

The adhesive layer includes a first glue portion distributed on the back of the window area and a second glue portion integrally connected to the periphery of the first glue portion and extending to the back of the ink area. The first glue portion and the second glue portion are made of the same material. When the second glue portion and the first glue portion are used to bond the substrate and other layers of the display panel PNL, if they are in a high temperature and high humidity environment for a long time, the bonding effect between the substrate and other layers of the display panel PNL will be weaken, and an edge of the display panel PNL will debond and wrinkle.

An edge of a light emitting side of the display panel PNL has a certain non-luminous area, namely, a peripheral area BB, which is usually 0.2 mm to 5 mm in width. In the assembly of the display 1, the bonding ability of the non-luminous area (peripheral area BB) may be improved by using an adhesive layer manufactured with a special material in the non-luminous area (peripheral area BB), so that the cover plate 2 may form an excellent bonding relationship with the display panel PNL and other layers through the adhesive layer, thereby improving the debonding and wrinkling problems caused by internal stress or rebound force after assembly and molding, and at the same time does not affect the optical characteristics of the light emitting side of the display panel PNL.

Specifically, the embodiment of the present disclosure provides a display, including a display panel PNL, an adhesive layer and a cover plate 2 which are arranged in a stacked manner. The light emitting side of the display panel PNL has the display area AA and the peripheral area BB surrounding the display area AA;

The adhesive layer includes an edge adhesive layer 5 disposed in the peripheral area BB and a main adhesive layer 4 covering the display area AA. A shear storage modulus of the edge adhesive layer 5 is greater than a shear storage modulus of the main adhesive layer 4.

The present disclosure provides a display, in which the display panel PNL is assembled into the cover plate 2 by lamination, and the display area AA is bonded by using the main adhesive layer 4 of an existing material, and the peripheral area BB is bonded by using an edge adhesive layer 5 with a larger shear storage modulus, thereby improving the bonding ability between the peripheral area BB on the light emitting side of the display panel PNL and the cover plate 2, improving the reliability of the display 1, especially the edge stability of the display 1 in a high temperature and high humidity environment for a long time, and at the same time, improve the impact resistance and drop resistance of the edge of the display 1 without affecting optical characteristics of the display area AA on the light emitting side of the display panel PNL.

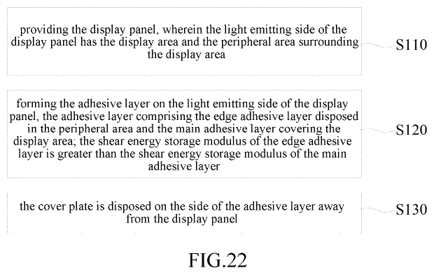

As shown in FIG. 22, the display 1 may be manufactured by the following manufacture method:
Step S110, providing a display panel PNL, wherein a light emitting side of the display panel PNL has a display area AA and a peripheral area BB surrounding the display area AA;
Step S120, forming an adhesive layer on the light emitting side of the display panel PNL, the adhesive layer comprising an edge adhesive layer 5 arranged in the peripheral area BB and a main adhesive layer 4 covering the display area AA; the shear storage modulus of the edge adhesive layer 5 is greater than the shear storage modulus of the main adhesive layer 4;
Step S130, disposing a cover plate 2 on a side of the adhesive layer away from the display panel PNL.

A detailed description of the components of the display 1 provided in the embodiment of the present disclosure in conjunction with the accompanying drawings:

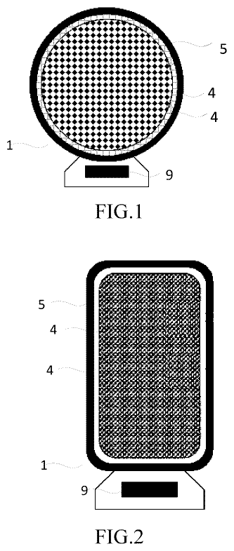

As shown in FIG. 1, a circular display 1 is shown, wherein a middle portion is an effective display area, namely, the display area AA, and the middle portion is bonded by the transparent main adhesive layer 4, the main adhesive layer 4 covers the display area AA, and an outer periphery of the main adhesive layer 4 is the edge adhesive layer 5, and a display driver chip 9 is arranged below the main adhesive layer 4. As shown in FIG. 2, a square display 1 is shown, and the structure of the square display 1 is the same as that of the circular display 1.

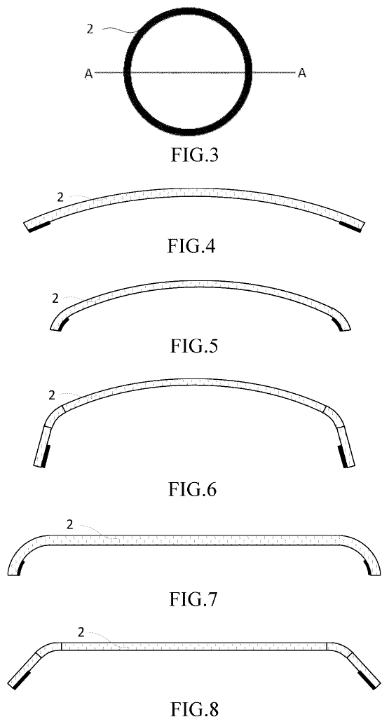

The present embodiment is based on the circular display 1 for structural introduction. As shown in FIG. 3, it is a front view of the cover plate 2 in the circular display 1.

In a disclosed embodiment, the cover plate 2 is a three-dimensional structure with a certain depth, and a vertical distance from at least one edge of the cover plate 2 to the center of the cover plate 2 is greater than a thickness of the cover plate 2 itself (that is, an angle formed by at least one edge point of the cover plate 2 and a line connecting its opposite edge point and the center of the cover plate 2 is less than 180°).

In a disclosed embodiment, the cover plate 2 in the present disclosure includes a curved surface.

In a disclosed embodiment, the cover plate 2 is a developable curved surface structure, a non-developable curved surface structure, or a structure of a developable curved surface and a non-developable curved surface spliced together.

In a disclosed embodiment, as shown in FIG. 3, the front view of the cover plate 2 is circular, wherein a first A=A cross-sectional structure of the cover plate 2 is shown in FIG. 4, and the cover plate 2 is a non-developable curved surface, or, a second A=A cross-sectional structure of the cover plate 2 is shown in FIG. 5, and the cover plate 2 is formed by splicing two non-developable curved surfaces, or, a third A=A cross-sectional structure of the cover plate 2 is shown in FIG. 6, and the cover plate 2 is formed by sequentially splicing two non-developable curved surfaces and one developable curved surface, or, a fourth A=A cross-sectional structure of the cover plate 2 is shown in FIG. 7, and the cover plate 2 is formed by splicing a developable curved surface and a non-developable curved surface, or, a fifth A=A cross-sectional structure of the cover plate 2 is shown in FIG. 8, and the cover plate 2 is formed by staggered splicing two developable curved surfaces and one non-developable curved surface.

In a disclosed embodiment, the curved surface is a non-developable curved surface. When the cover plate 2 including the non-developable curved surface is curvedly laminated with the display panel PNL, it is more likely to have problems such as debonding and wrinkling caused by internal stress or rebound force after assembly. By adopting the solution disclosed in the present disclosure, an excellent bonding relationship may be formed between the non-developable curved surface of the cover plate 2 and the display panel PNL, thereby improving the problems of debonding and wrinkling caused by internal stress or rebound force after assembly, and at the same time, it does not affect the optical characteristics of the light emitting side of the display panel PNL.

In a disclosed embodiment, the cover plate 2 may be a conical side, a cylindrical side, a partial sphere, or a structure where a partial plane and a partial sphere are combined.

In a disclosed embodiment, an adhesive layer material of the edge adhesive layer 5 is different from that of the main adhesive layer 4. The main adhesive layer 4 is a material such as OCA optical glue, and after sufficient reaction and curing, the shear storage modulus G′ at room temperature (25°) is 100 kPa. The edge adhesive layer 5 is a polymer adhesive, and after sufficient reaction and curing, the shear storage modulus G′ of the polymer adhesive at room temperature (25°) is ≥300 kPa. The polymer adhesive is a type of adhesive material with a polymer compound as a main body, also known as a polymer binder or a polymer adhesive. The present disclosure uses a polymer adhesive with a shear storage modulus G′≥300 kPa at room temperature (25°) after sufficient reaction and curing to bond the peripheral area BB of the display panel PNL and the cover plate 2, so as to improve the bonding ability between the cover plate 2 and the peripheral area BB of the display panel PNL. The adhesive layer material has the characteristics of an increased shear storage modulus under a low temperature condition and a decreased shear storage modulus under a high temperature condition.

In a disclosed embodiment, the polymer adhesive is black or another color, translucent or transparent.

In a disclosed embodiment, the polymer adhesive is transparent, and the transparent polymer adhesive has a better curing condition.

In a disclosed embodiment, the polymer adhesive is black, and the black polymer adhesive may replace a portion of the ink layer on the cover plate 2. When printing the ink layer of the cover plate 2, corresponding workload may be reduced, thereby speeding up the manufacture efficiency of the cover plate 2.

In a disclosed embodiment, the edge adhesive layer 5 is one of modified acrylic resin, modified polyurethane resin, modified organic silicone resin, modified epoxy resin, or a combination thereof.

In a disclosed embodiment, the edge adhesive layer 5 is a modified acrylic resin, which is transparent, has a good curing condition, and does not undergo further cross-linking during a film-forming process. Therefore, it has a large relative molecular weight, good gloss and color retention, good water and chemical resistance, and is fast drying, easy processing, and easy construction, recoating and rework.

In a disclosed embodiment, in order to increase a contact area between the edge adhesive layer 5 and the cover plate 2 and the peripheral area BB of the display panel PNL, and thereby increase the bonding reliability between the cover plate 2 and the peripheral area BB of the display panel PNL, a width of the edge adhesive layer 5 is set to be greater than or equal to 0.15 mm, that is, W1 in FIGS. 13-15 is greater than or equal to 0.15 mm.

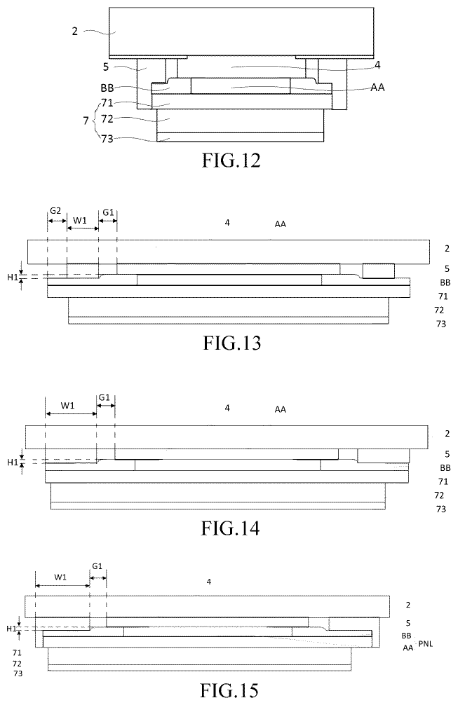

In a disclosed embodiment, the main adhesive layer 4 and the edge adhesive layer 5 do not overlap with each other. The positions of the main adhesive layer 4 and the edge adhesive layer 5 may be distinguished, and the main adhesive layer 4 and the edge adhesive layer 5 may be prevented from overlapping to increase the thickness of the display 1. In order to meet the processing technology requirements, as shown in FIGS. 9 to 18, a gap is set between the main adhesive layer 4 and the edge adhesive layer 5. As shown in FIGS. 13 to 15, a width of the gap is G1, wherein G1 is greater than or equal to 0.1 mm. During the process, a certain processing error may occur. The setting of G1 is to provide a certain processing allowance for the processing error, further ensuring that the main adhesive layer 4 and the edge adhesive layer 5 do not overlap with each other. At the same time, according to the physical feature of the gap between the main adhesive layer 4 and the edge adhesive layer 5, it is convenient to manufacture the adhesive layer and speed up the manufacture efficiency.

In a disclosed embodiment, as shown in FIGS. 13-15, a thickness of the display panel PNL at an edge of the peripheral area BB is a first thickness, and a thickness of the display panel PNL on an inner side of the peripheral area BB is a second thickness. The first thickness is at least 10 microns smaller than the second thickness, that is, H1 in the figure is not less than 10 microns, and the edge adhesive layer 5 covers at least a portion of the edge of the peripheral area BB. The edge adhesive layer 5 is arranged at the edge of the peripheral area BB with a smaller thickness, which facilitates positioning of the edge adhesive layer 5 when manufacturing the display 1.

In a disclosed embodiment, a thinned area is provided at the edge of the peripheral area BB of the display panel PNL, and the edge adhesive layer 5 covers at least part of the thinned area, that is, H1 in the drawings is not less than 10 microns, which facilitates positioning of the edge adhesive layer 5 when manufacturing the display 1.

In a disclosed embodiment, as shown in FIG. 9, a polarizing layer 6 is provided on the light emitting side of the display panel PNL, and a main adhesive layer 4 is used to bond the polarizing layer 6 and the cover plate 2. The method for manufacturing the display further includes bonding the polarizing layer 6 on the display area AA on the light emitting side of the display panel PNL.

In a disclosed embodiment, as shown in FIGS. 9-12 and FIGS. 16-18, the display 1 further includes a back support layer 7 disposed on a non-light emitting side of the display panel PNL.

In a disclosed embodiment, the edge adhesive layer 5 extends out of the edge of the display panel PNL and is connected to the back support layer 7.

In a disclosed embodiment, the back support layer 7 includes a back film 71, a foam 72 and a copper foil 73 which are sequentially bonded to the non-light emitting side of the display panel PNL from near to far.

The method for manufacturing the display further includes sequentially bonding the back film 71, the foam 72, and the copper foil 73 to the non-light emitting surface of the display panel PNL.

In a disclosed embodiment, as shown in FIG. 9, a flat-panel display 1 is shown, and the display 1 includes the copper foil 73, the foam 72, the back film 71, the display panel PNL, the polarizing layer 6, the adhesive layer and the cover plate 2 which are sequentially stacked, wherein the adhesive layer includes the main adhesive layer 4 and the edge adhesive layer 5. A gap is provided between the edge adhesive layer 5 and the main adhesive layer 4. The main adhesive layer 4 is used to bond the polarizing layer 6 and the cover plate 2, and the edge adhesive layer 5 is used to bond the ink area of the cover plate 2 to the peripheral area BB of the display panel PNL.

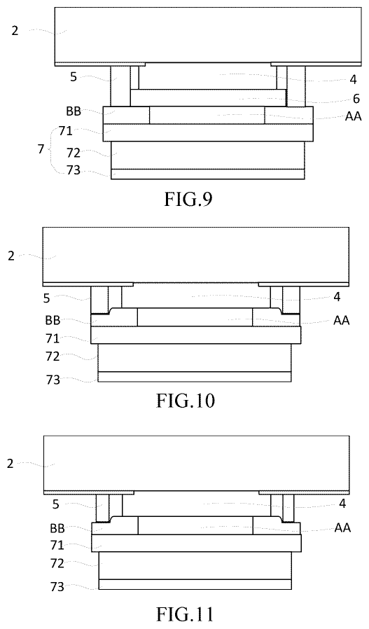

In a disclosed embodiment, as shown in FIG. 10 and FIG. 14, a flat-panel display 1 is provided, and the display 1 includes the copper foil 73, the foam 72, the back film 71, the display panel PNL, the adhesive layer and the cover plate 2 which are stacked in sequence. The adhesive layer includes the main adhesive layer 4 and the edge adhesive layer 5. The thinned area is provided at the edge of the peripheral area BB of the display panel PNL. The main adhesive layer 4 is used for bonding the display area AA, part of the peripheral area BB and the cover plate 2 of the display panel PNL. The edge adhesive layer 5 is provided in the thinned area. A gap is provided between the edge adhesive layer 5 and the main adhesive layer 4, and is used for bonding the edges of the ink area of the cover plate 2 and the peripheral area BB. The width of the edge adhesive layer 5 is equal to a width of the thinned area.

In a disclosed embodiment, as shown in FIG. 11 and FIG. 13, a difference between FIG. 11 and FIG. 10 is that the width of the edge adhesive layer 5 is smaller than the width of the thinned area, that is, the sum of G2 and W1 is the width of the thinned area, and the edge adhesive layer 5 is arranged on an inner side of the thinned area.

In a disclosed embodiment, as shown in FIG. 15, a difference between FIG. 15 and FIG. 10 is that the edge adhesive layer 5 extends out of the display panel PNL and is connected to the back support layer 7.

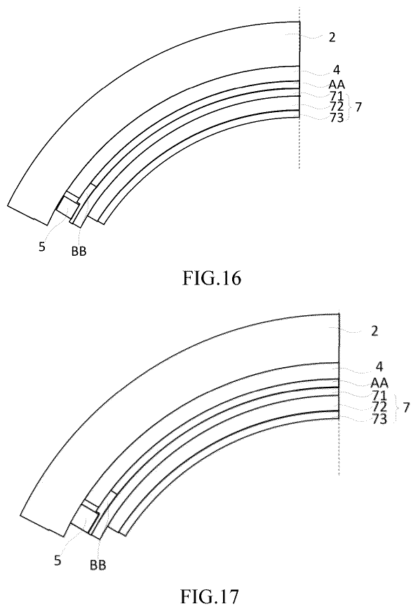

In a disclosed embodiment, as shown in FIG. 16, a difference between FIG. 16 and FIG. 11 is that FIG. 15 is a curved display 1.

In a disclosed embodiment, as shown in FIG. 18, a difference between FIG. 18 and FIG. 10 is that FIG. 16 is a curved display 1.

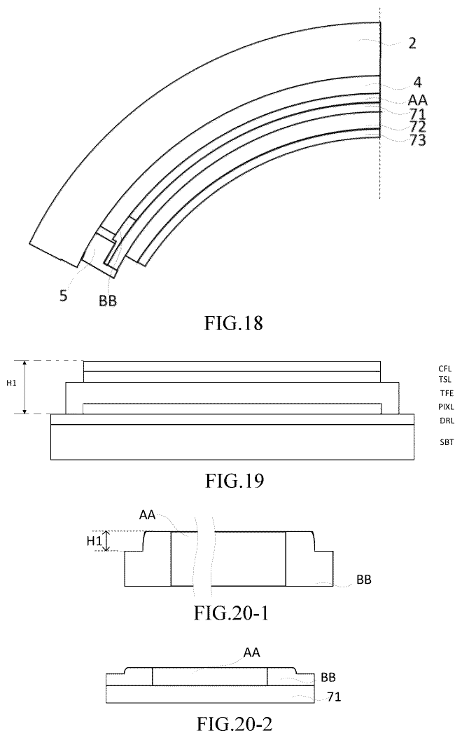

In a disclosed embodiment, as shown in FIG. 19, a difference between FIG. 19 and FIG. 14 is that FIG. 17 is a curved display 1.

In a disclosed embodiment, a side dimension of at least one structure in the back support layer 7 is larger than a side that extends beyond the edge of the display panel PNL, and the edge adhesive layer 5 extends out of the peripheral area BB of the display panel PNL and connects the structure in the back support layer 7 with the cover plate 2, thereby improving the bonding ability of the back support layer 7. Specifically, the edge adhesive layer 5 extends outward from the edge of the display panel PNL and directly bonds the structure in the back support layer 7 with the cover plate 2.

In a disclosed embodiment, as shown in FIG. 19, the display panel PNL includes a flexible base layer (substrate SBT), a circuit layer (driving layer DRL), a light emitting layer (pixel layer PIXL), an encapsulation layer (thin film encapsulation layer TFE), a touch screen layer (touch function layer TSL) and a color film layer CFL which are sequentially stacked.

In a disclosed embodiment, the edge adhesive layer 5 is made of the same material as the main adhesive layer 4, and has the shear storage modulus of not less than 300 kPa at 25°C.

The present disclosure provides a display device, comprising the display 1 described above.

The display 1 in the display device provided by the present disclosure has the same structure as the display 1 described in the above embodiment, and therefore has the same beneficial effects, which will not be described in detail in the present disclosure.

The display 1 obtained by the method for manufacturing the display provided by the present disclosure has the same structure as the display 1 described in the above embodiment, and therefore has the same beneficial effects, which will not be described in detail in the present disclosure.

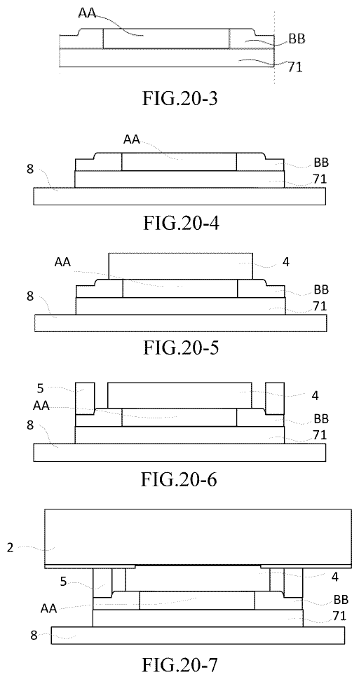

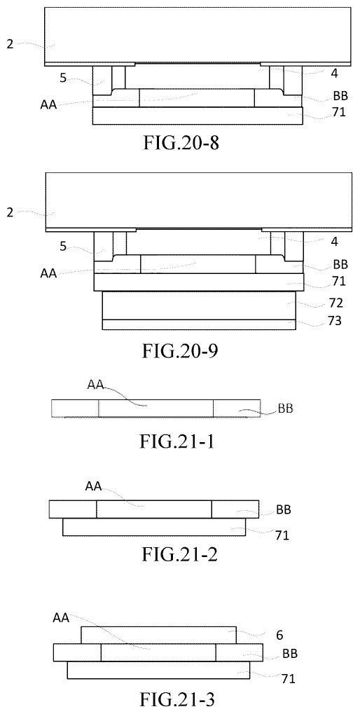

In a disclosed embodiment, as shown in FIG. 20, a method for manufacturing the display comprises following steps:
S110, as shown in FIG. 20-1, providing the display panel PNL, wherein the light emitting side of the display panel PNL has the display area AA and the peripheral area BB surrounding the display area AA, wherein the peripheral area BB has the thinned area;
S111, as shown in FIG. 20-2, bonding the back film 71 to the non-light emitting side of the display panel PNL;
S112, as shown in FIG. 20-3, integrally cutting the display panel PNL and the back film 71 by laser;
S113, as shown in FIG. 20-4, bonding a carrier film 8 to the side of the back film 71 away from the display panel PNL;
S120, forming the adhesive layer on the light emitting side of the display panel PNL, the adhesive layer comprising the edge adhesive layer 5 disposed in the peripheral area BB and a main adhesive layer 4 covering the display area AA; the shear storage modulus of the edge adhesive layer 5 is greater than the shear storage modulus of the main adhesive layer 4;

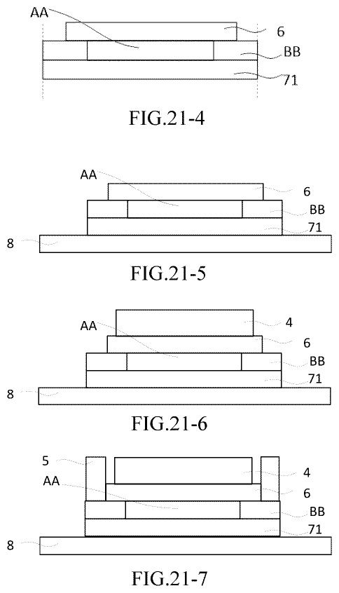

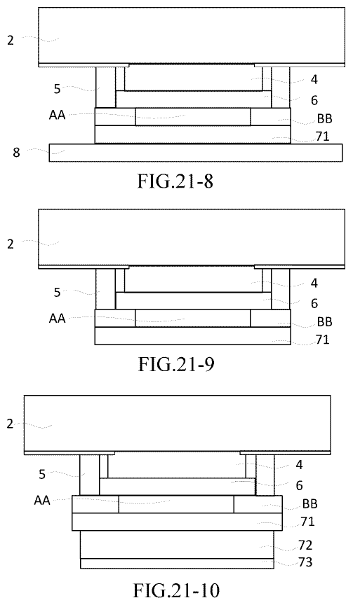

Specifically, as shown in FIG. 20-5, the main adhesive layer 4 is bonded to the light emitting side of the display panel PNL; as shown in FIG. 21-6, the edge adhesive layer 5 is formed after glue is applied to the thinned area on the light emitting side of the display panel PNL and pre-cured;
S130, as shown in FIG. 20-7, the cover plate 2 is disposed on the side of the adhesive layer away from the display panel PNL;
S131, as shown in FIG. 20-8, removing the carrier film 8;
S140-2, as shown in FIG. 20-9, the foam 72 and the copper foil 73 are bonded in sequence to complete the manufacture of the display 1.

The display manufactured by the above method includes the copper foil 73, the foam 72, the back film 71, the display panel PNL, the adhesive layer and the cover plate 2 which are stacked in sequence, wherein the adhesive layer includes the edge adhesive layer 5 of a thinned layer arranged in the peripheral area BB and the main adhesive layer 4 covering the display area AA.

In a disclosed embodiment, as shown in FIG. 21, a method for manufacturing the display comprises following steps:
S110, as shown in FIG. 21-1, providing a display panel PNL, wherein the light emitting side of the display panel PNL has the display area AA and the peripheral area BB surrounding the display area AA;
S111, as shown in FIG. 21-2, bonding the back film 71 to the non-light emitting side of the display panel PNL;
S112, as shown in FIG. 21-3, bonding the polarizing layer 6 to the light emitting side of the display panel PNL;
S113, as shown in FIG. 21-4, integrally cutting the display panel PNL and the back film 71 by laser;
S114, as shown in FIG. 21-5, bonding the carrier film 8 to the side of the back film 71 away from the display panel PNL;
S120, forming the adhesive layer on the light emitting side of the display panel PNL, the adhesive layer comprising the edge adhesive layer 5 disposed in the peripheral area BB and the main adhesive layer 4 covering the display area AA; the shear storage modulus of the edge adhesive layer 5 is greater than the shear storage modulus of the main adhesive layer 4;

Specifically, as shown in FIG. 21-6, the main adhesive layer 4 is bonded to the light emitting side of the display panel PNL; as shown in FIG. 20-7, the edge adhesive layer 5 is formed after glue is applied to the thinned area on the light emitting side of the display panel PNL and pre-cured;
S130, as shown in FIG. 21-8, the cover plate 2 is disposed on the side of the adhesive layer away from the display panel PNL;
S131, as shown in FIG. 21-9, removing the carrier film 8;
S132, as shown in FIG. 21-10, the foam 72 and the copper foil 73 are bonded in sequence to complete the manufacture of the display 1.

The display manufactured by the above method includes the copper foil 73, the foam 72, the back film 71, the display panel PNL, the adhesive layer and the cover plate 2 stacked in sequence, wherein the adhesive layer includes the edge adhesive layer 5 arranged at the edge of the peripheral area BB and the main adhesive layer 4 covering the display area AA.
the present disclosure are described in a specific order in the drawings, this does not require or imply that the steps must be performed in this specific order, or that all the steps shown must be performed to achieve the desired results. Additionally or alternatively, some steps may be omitted, multiple steps may be combined into one step, and/or one step may be decomposed into multiple steps, etc.

Those skilled in the art will readily appreciate other embodiments of the present disclosure after considering the specification and practicing the disclosure disclosed herein. This application is intended to cover any modification, use or adaptation of the present disclosure, which follows the general principles of the present disclosure and includes common knowledge or customary techniques in the art that are not disclosed in the present disclosure. The specification and examples are intended to be exemplary only, and the true scope and spirit of the present disclosure are indicated by the appended claims.

1. A display, comprising a display panel, an adhesive layer and a cover plate which are arranged in a stacked manner, wherein a light emitting side of the display panel has a display area and a peripheral area surrounding the display area;
wherein the adhesive layer comprises an edge adhesive layer arranged in the peripheral area and a main adhesive layer covering the display area, and a shear storage modulus of the edge adhesive layer is greater than a shear storage modulus of the main adhesive layer.

2. The display according to claim 1, wherein at least a portion of a surface of the cover plate is a curved surface.

3. The display according to claim 2, wherein at least a portion of the surface of the cover plate is a non-developable curved surface.

4. The display according to claim 1, wherein the shear storage modulus of the edge adhesive layer at 25° C. is not less than 300 kPa.

5. The display according to claim 1, wherein the main adhesive layer and the edge adhesive layer do not overlap each other.

6. The display according to claim 5, wherein the display panel has a first thickness at an edge of the peripheral area, and the display panel has a second thickness at an inner side of the peripheral area, wherein the first thickness is at least 10 micrometers smaller than the second thickness; and
wherein the edge adhesive layer covers at least a portion of the edge of the peripheral area.

7. The display according to claim 5, wherein the display panel is provided with a thinned area at an edge of the peripheral area, and the edge adhesive layer covers at least a portion of the thinned area.

8. The display according to claim 1, wherein a width of the edge adhesive layer is not less than 0.15 mm.

9. The display of claim 1, wherein the edge adhesive layer is black.

10. The display according to claim 1, wherein the edge adhesive layer is transparent or translucent.

11. The display according to claim 1, wherein the edge adhesive layer is at least one of modified acrylic resin, modified polyurethane resin, modified organosiloxane resin, and modified epoxy resin.

12. The display according to claim 1, further comprising a back support layer disposed on a non-light emitting side of the display panel;
wherein the edge adhesive layer extends out of an edge of the display panel and is connected to the back support layer.

13. The display according to claim 1, wherein the display panel is a flexible display panel.

14. The display according to claim 2, wherein a surface of an edge region of the cover plate is a curved surface.

15. The display according to claim 1, wherein the edge adhesive layer is made of the same material as the main adhesive layer and the shear storage modulus of the edge adhesive layer is not less than 300 kPa at 25° C.

16. A display device, comprising the display according to claim 1.

17. A method for manufacturing a display, comprising following steps:
providing a display panel, wherein a light emitting side of the display panel has a display area and a peripheral area surrounding the display area;
forming an adhesive layer on the light emitting side of the display panel, wherein the adhesive layer comprises an edge adhesive layer arranged in the peripheral area and a main adhesive layer covering the display area, and wherein a shear storage modulus of the edge adhesive layer is greater than a shear storage modulus of the main adhesive layer;
providing a cover plate on a side of the adhesive layer away from the display panel.
